(19) United States
(12) Patent Application Publication
(10) Pub. No.: US 2025/0320626 A1
(43) Pub. Date: Oct. 16, 2025

(54) DOPANT ADDITION METHOD, MONOCRYSTALLINE SILICON MANUFACTURING METHOD, DOPANT ADDITION CONTROL DEVICE, AND MONOCRYSTALLINE SILICON MANUFACTURING SYSTEM

(71) Applicant: SUMCO CORPORATION, Tokyo (JP)

(72) Inventor: Hiroyuki OOTA, Nagasaki (JP)

(73) Assignee: SUMCO CORPORATION, Tokyo (JP)

(21) Appl. No.: 19/176,896

(22) Filed: Apr. 11, 2025

(30) Foreign Application Priority Data
Apr. 16, 2024 (JP) 2024-066285

(51) Int. Cl. C30B 15/04; C30B 15/20; C30B 29/06

(52) U.S. Cl. CPC C30B 15/04; C30B 15/20; C30B 29/06

(57) ABSTRACT

A dopant addition method includes: attaching a dopant adding device charged with a volatile solid dopant to a first end of a wire, lowering the dopant adding device to an adding position above a surface of a silicon melt in a crucible placed in a chamber, and blowing a dopant gas generated by sublimation of the solid dopant to the silicon melt; and determining that addition of the dopant to the silicon melt is completed when a weight of the dopant adding device attached to the first end of the wire detected by a weight detector reaches a standard state, and moving the dopant adding device upward, in which the standard state is a state where the weight detected by the weight detector no longer changes or a state where the weight detected by the weight detector is equal to a weight of the dopant adding device alone.

### CROSS REFERENCE TO RELATED APPLICATIONS

The entire disclosure of Japanese Patent Application No. 2024-066285 filed Apr. 16, 2024 is expressly incorporated by reference herein.

### TECHNICAL FIELD

The present invention relates to a dopant addition method, a monocrystalline silicon manufacturing method, a dopant addition control device, and a monocrystalline silicon manufacturing system.

### BACKGROUND ART

In the manufacture of monocrystalline silicon, there is known a method of adding a volatile dopant to a silicon melt in which the dopant is sublimated to generate a dopant gas, and the dopant gas is blown to the silicon melt (see, for instance, Literature 1: JP 2001-342094 A).

Literature 1 discloses a doping device including: a container that includes a container body and a discharge tube; and an outer cylinder that houses the container body and is open at its lower end. When the doping device is lowered to a position near the surface of the silicon melt, solid arsenic (solid dopant) in the container body is sublimated by radiation heat of the silicon melt to generate arsenic gas (dopant gas). When the dopant gas is released from a lower end of the discharge tube to be blown to the silicon melt, the dopant contained in the dopant gas is dissolved to be added to the silicon melt.

Literature 1, however, does not disclose how to determine whether the dopant addition is completed.

It is difficult to directly visually check an interior of the container body in the arrangement disclosed in Literature 1. As a method for determining the completion of dopant addition, it is conceivable a method of determining the completion of dopant addition when a predetermined time has elapsed after the doping device is lowered to an adding position near the silicon melt, irrespective of the charged amount of the solid dopant in the doping device.

However, the sublimation rate of the solid dopant may change depending on the pressure or temperature in a chamber, a change in heat environment due to deterioration or replacement of components of a hot zone, and the like. Thus, even when the same amount of dopant is added, sublimation of all the solid dopant may be completed earlier or later than the predetermined time.

When the sublimation of the solid dopant is completed earlier than the predetermined time, despite the completion of the sublimation of the solid dopant, a growth step of monocrystalline silicon cannot be performed until the predetermined time has elapsed. Thus, the production efficiency cannot be improved. In addition, the dopant added to the silicon melt may evaporate before the predetermined time has elapsed. Thus, the monocrystalline silicon may not have desired resistivity.

When the sublimation of the solid dopant is completed later than the predetermined time, the monocrystalline silicon is produced before all the dopant has been added. Thus, the monocrystalline silicon may not have desired resistivity.

### SUMMARY OF THE INVENTION

An object of the invention is to provide a dopant addition method, a monocrystalline silicon manufacturing method, a dopant addition control device, and a monocrystalline silicon manufacturing system which are capable of appropriately determining completion of addition of the dopant.

A dopant addition method according to an aspect of the invention includes: attaching a dopant adding device charged with a volatile solid dopant to a first end of a wire, lowering the dopant adding device to an adding position above a surface of a silicon melt in a crucible placed in a chamber, and blowing a dopant gas generated by sublimation of the solid dopant to the silicon melt; and determining that addition of the dopant to the silicon melt is completed when a weight of the dopant adding device attached to the first end of the wire detected by a weight detector reaches a standard state, and moving the dopant adding device upward, in which the standard state is a state where the weight detected by the weight detector no longer changes or a state where the weight detected by the weight detector is equal to a weight of the dopant adding device alone.

In the dopant addition method according to the above aspect of the invention, it is preferable that it is determined that the addition of the dopant to the silicon melt is completed when a predetermined standby period has elapsed since the standard state is reached, and that the standby period is a period from a time when the standard state is reached to all the dopant gas in the dopant adding device is presumed to be blown to the silicon melt.

In the dopant addition method according to the above aspect of the invention, it is preferable that a drum configured to be rotated by driving a motor to wind or unwind the wire is fixed to a second end of the wire, that the weight detector is a load cell configured to detect a load acting on the motor to detect the weight of the dopant adding device attached to the first end of the wire, and that the dopant adding device is configured to be moved by controlling the motor.

A monocrystalline silicon manufacturing method according to another aspect of the invention includes: adding the dopant to the silicon melt by the above dopant addition method; and growing monocrystalline silicon by a Czochralski method using the silicon melt to which the dopant is added.

A dopant addition control device according to still another aspect of the invention includes: an addition start controller configured to lower a dopant adding device charged with a volatile solid dopant and attached to a first end of a wire to an adding position above a surface of a silicon melt in a crucible and to blow a dopant gas generated by sublimation of the solid dopant to the silicon melt; and an addition termination controller configured to determine that addition of the dopant to the silicon melt is completed when a weight of the dopant adding device attached to the first end of the wire detected by a weight detector reaches a standard state, and to move the dopant adding device upward, in which the standard state is a state where the weight detected by the weight detector no longer changes or a state where the weight detected by the weight detector is equal to a weight of the dopant adding device alone.

In the dopant addition control device according to the above aspect of the invention, it is preferable that the addition termination controller is configured to determine that the addition of the dopant to the silicon melt is completed when a predetermined standby period has elapsed since the standard state is reached, and that the standby period is a period from a time when the standard state is reached to all the dopant gas in the dopant adding device is presumed to be blown to the silicon melt.

In the dopant addition control device according to the above aspect of the invention, it is preferable that a drum configured to be rotated by driving a motor to wind or unwind the wire is fixed to a second end of the wire, that the weight detector is a load cell configured to detect a load acting on the motor to detect the weight of the dopant adding device attached to the first end of the wire, and that the addition start controller and the addition termination controller are configured to control the motor to move the dopant adding device.

A monocrystalline silicon manufacturing system according to further aspect of the invention includes: the above dopant addition control device; the dopant adding device; the wire having a first end to which the dopant adding device or a seed crystal is attached; the weight detector; and a growth controller configured to grow monocrystalline silicon by pulling up the seed crystal attached to the first end of the wire after bringing the seed crystal into contact with the silicon melt to which the dopant is added.

A monocrystalline silicon manufacturing system according to still further aspect of the invention includes: the above dopant addition control device; the dopant adding device; a pulling drive unit including the wire having the first end to which the dopant adding device or a seed crystal is attached, the drum, and the motor; the load cell; and a growth controller configured to grow monocrystalline silicon by pulling up the seed crystal attached to the first end of the wire after bringing the seed crystal into contact with the silicon melt to which the dopant is added.

### BRIEF DESCRIPTION OF DRAWINGS

FIG. 1 schematically illustrates a monocrystalline silicon manufacturing system according to an exemplary embodiment, in which monocrystalline silicon is being grown.

FIG. 2 schematically illustrates the monocrystalline silicon manufacturing system according to the exemplary embodiment, in which a dopant is being added.

FIG. 3 is a vertical cross-sectional view of a dopant adding device according to the exemplary embodiment.

FIG. 4 is a graph illustrating a relationship between time and weight detected by a load cell in a dopant addition method according to the exemplary embodiment.

FIG. 5 is a flowchart of a monocrystalline silicon manufacturing method according to the exemplary embodiment.

FIG. 6 is a flowchart of a dopant addition step according to the exemplary embodiment.

### DETAILED DESCRIPTION

### Exemplary Embodiment

### Configuration of Monocrystalline Silicon Manufacturing System

First, a configuration of a monocrystalline silicon manufacturing system according to an exemplary embodiment of the invention will be described below.

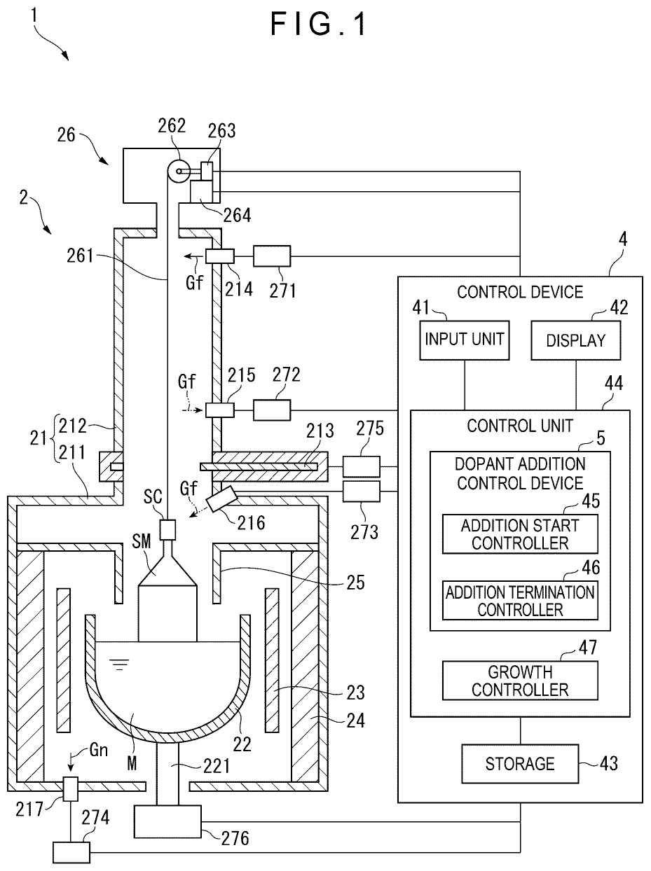

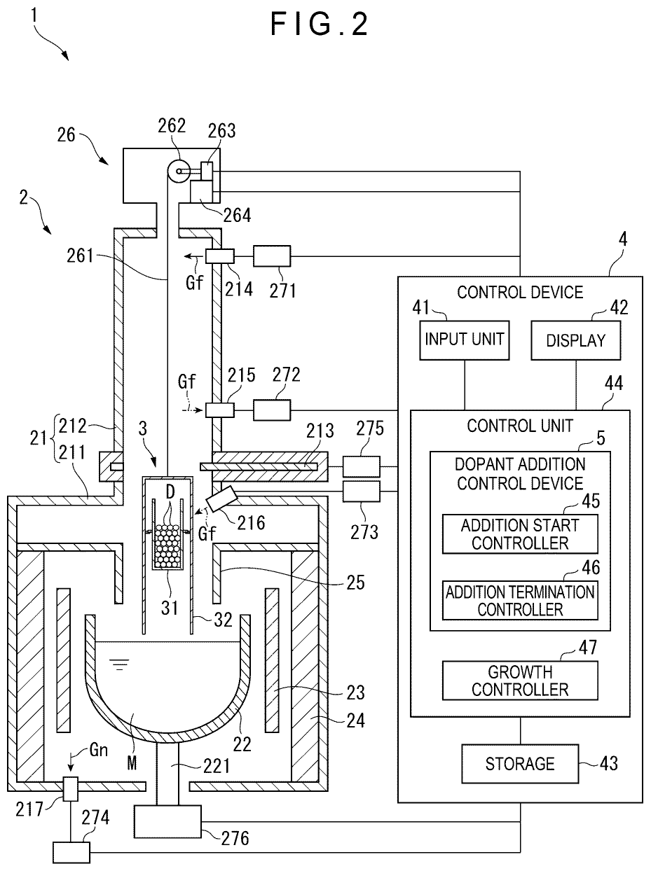

A monocrystalline silicon manufacturing system 1 illustrated in FIGS. 1 and 2 includes a monocrystalline silicon manufacturing apparatus 2.

The monocrystalline silicon manufacturing apparatus 2 uses the Czochralski (CZ) method to produce monocrystalline silicon (ingot) SM to which a volatile dopant is added. Examples of the volatile dopant include arsenic, red phosphorus, and antimony. The monocrystalline silicon manufacturing apparatus 2 includes a chamber 21, a crucible 22, a heater 23, a heat insulating cylinder 24, a shield 25, and a pulling drive unit 26.

The chamber 21 includes a main chamber 211 in which the monocrystalline silicon SM is pulled up, and a pull chamber 212 which is connected to an upper part of the main chamber 211 and in which the pulled-up monocrystalline silicon SM is accommodated.

The main chamber 211 houses the crucible 22, the heater 23, the heat insulating cylinder 24, and the shield 25.

A gate valve 213, which isolates an upper end of the main chamber 211 from a lower end of the pull chamber 212, is provided for a lower part of the pull chamber 212.

A first gas supply section 214, through which inert gas Gf (e.g., argon (Ar) gas) is supplied into the pull chamber 212, is provided for an upper part of the pull chamber 212. A first gas discharge section 215, through which the inert gas Gf is discharged from the pull chamber 212, is provided for the lower part of the pull chamber 212. A second gas supply section 216, through which the inert gas Gf is introduced into the chamber 21, is provided for the upper part of the main chamber 211. A second gas discharge section 217, through which internal gas Gn (e.g., Ar gas containing evaporant such as SiO generated in the main chamber 211) is discharged out of the system of the monocrystalline silicon manufacturing apparatus 2, is provided for a lower part of the main chamber 211.

The crucible 22 includes an outer graphite crucible and an inner quartz crucible. The crucible 22, which is provided in the main chamber 211, stores a silicon melt M to which a volatile dopant is added. The crucible 22 is fixed to an upper end of a support shaft 221 that can rotate and move up and down.

The heater 23 is a hollow cylindrical component disposed to surround the crucible 22. The heater 23 generates heat to melt the silicon material in the crucible 22.

The heat insulating cylinder 24 is a hollow cylindrical component disposed to surround the heater 23.

The shield 25 is a substantially hollow cylindrical component made from a carbon material. The shield 25 surrounds the monocrystalline silicon SM being pulled up from the silicon melt M to block radiation heat from the heater 23 to the monocrystalline silicon SM.

The pulling drive unit 26 is provided for a top of the pull chamber 212. The pulling drive unit 26 includes a wire 261, a drum 262, a motor 263, and a load cell 264 serving as a weight measurement unit.

A seed crystal SC illustrated in FIG. 1 or a dopant adding device 3 illustrated in FIG. 2 is attached to a first end of the wire 261.

The drum 262 is fixed to a second end of the wire 261. The drum 262 provided above the crucible 22 is rotated by the drive of the motor 263, thereby winding and unwinding the wire 261 with the wire 261 being kept coaxial with the support shaft 221.

The load cell 264 detects a load acting on the motor 263 to detect a weight of the monocrystalline silicon SM or the dopant adding device 3 attached to the first end of the wire 261.

The monocrystalline silicon manufacturing system 1 further includes the dopant adding device 3.

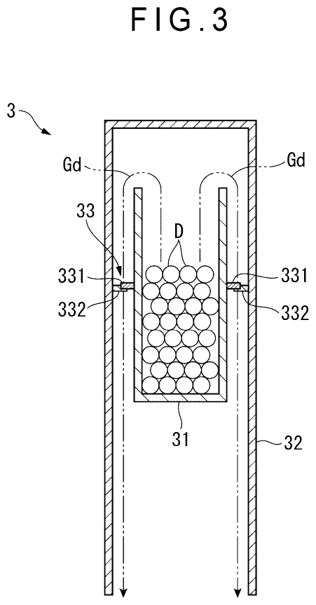

The dopant adding device 3 adds a volatile dopant into the silicon melt M stored in the crucible 22. As illustrated in FIG. 3, the dopant adding device 3 includes a dopant holder 31, an outer cylinder 32, and a support unit 33.

The dopant holder 31 is made from quartz. The dopant holder 31 is a bottomed hollow cylindrical component having an open upper end and a closed lower end. A dopant D in a form of a solid (hereinafter occasionally referred to as a “solid dopant”) is charged in the dopant holder 31. The solid dopant D is sublimated by radiation heat from the silicon melt M to generate a dopant gas Gd, as indicated by two-dot-dash line in FIG. 3. The generated dopant gas Gd is released from an opening at an upper end of the dopant holder 31. The opening, through which the dopant gas Gd is released, may be provided for a side surface of the dopant holder 31.

The outer cylinder 32 is made from quartz. The outer cylinder 32 is a hollow cylindrical component having a closed upper end and an open lower end. The dopant holder 31 is provided in the outer cylinder 32. The dopant gas Gd released from the dopant holder 31 outflows from the outer cylinder 32 through the lower end thereof, and is blown to the silicon melt M.

The support unit 33 includes multiple supported members 331 made from a carbon material and multiple receiver members 332 each of which supports a lower surface of the corresponding one of the supported members 331. The supported members 331 are provided on an outer circumferential surface of the dopant holder 31 along its circumferential direction at regular intervals. The receiver members 332 are provided on an inner circumferential surface of the outer cylinder 32 along its circumferential direction at regular intervals.

Each of the supported members 331 is fitted to an upper surface of the corresponding one of the receiver members 332, so that the dopant holder 31 is supported within the outer cylinder 32. The dopant gas Gd released from the dopant holder 31 passes through a space between the dopant holder 31 and the outer cylinder 32 where the supported members 331 and the receiver members 332 are not provided, and outflows from the outer cylinder 32 through the lower end thereof.

The monocrystalline silicon manufacturing system 1 further includes a control device 4 as illustrated in FIGS. 1 and 2.

The control device 4 is connected to the load cell 264. Weight measurements detected by the load cell 264 are transferred to the control device 4 to be recorded.

The control device 4 is configured to control a first gas supply controller 271 for supplying the inert gas Gf from the first gas supply section 214 into the pull chamber 212, a first gas discharge controller 272 for discharging the inert gas Gf inside the pull chamber 212 through the first gas discharge section 215, a second gas supply controller 273 for supplying the inert gas Gf from the second gas supply section 216 into the chamber 21, a second gas discharge controller 274 for discharging the internal gas Gn inside the chamber 21 through the second gas discharge section 217, a gate valve driver 275 for driving the gate valve 213, a crucible driving unit 276 for rotating the crucible 22, the heater 23, and the motor 263.

The control device 4 includes an input unit 41, a display 42, a storage 43, and a control unit 44.

The input unit 41 includes. for instance, a touch panel or a physical button. The input unit 41 outputs a signal corresponding to an input operation to the control unit 44.

The display 42 displays various kinds of information under the control of the control unit 44.

The storage 43 stores various kinds of information relating to addition of the dopant and growth of the monocrystalline silicon SM in a manner readable by the control unit 44.

The control unit 44, which is provided with a CPU, achieves various functions by causing the CPU to execute programs stored in the storage 43. The control unit 44 includes an addition start controller 45, an addition termination controller 46, and a growth controller 47.

The addition start controller 45 and the addition termination controller 46 constitute a dopant addition control device 5, which controls addition of the dopant to the silicon melt M.

The addition start controller 45 moves the dopant adding device 3 accommodating the solid dopant D to an adding position near the silicon melt M, and the dopant gas Gd generated by sublimating the solid dopant D is blown to the silicon melt M. The adding position refers to a position for the solid dopant D in the dopant adding device 3 to be sublimated.

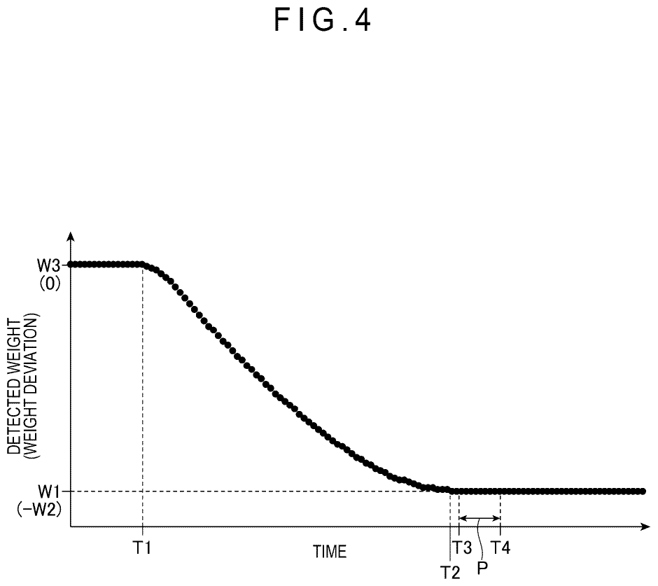

The addition termination controller 46 may determine that the addition of the dopant to the silicon melt M is completed at a time T3 when the weight detected by the load cell 264 reaches a standard state, as illustrated in FIG. 4. Alternatively, the addition termination controller 46 may determine that the addition of the dopant to the silicon melt M is completed at a time T4, which is a time when a standby period P has elapsed since the time T3 when the standard state is reached. When determining that the addition of the dopant is completed, the addition termination controller 46 controls the dopant adding device 3 to move upward.

The dopant adding device 3 is used to add the dopant to the silicon melt M. Assuming that the weight of the dopant adding device 3 is W1 and the total weight of the solid dopant D charged in the dopant adding device 3 is W2, the weight detected by the load cell 264 when the dopant gas Gd is not generated is a weight W3, which is the sum of the weight W1 and the weight W2, as illustrated in FIG. 4.

When the dopant adding device 3 is moved into the main chamber 211 and the dopant gas Gd begins to be generated as the dopant sublimates from a time T1, the weight detected by the load cell 264 gradually decreases from the weight W3 over time. The weight detected by the load cell 264 at a time T2 when all the solid dopant D in the dopant adding device 3 is sublimated, is the weight W1. When the weight W3 at the time when no dopant gas Gd is generated is used as the reference, the weight deviation at the time T1 is 0 (=W3−W3). The weight deviation at the time T2 is-W2 (=W1−W3=W1−(W1+W2)).

The weight detected by the load cell 264 does not change after the time T2. For instance, it can be determined that the standard state, where the weight (weight deviation) is unchanged, is reached at the time T3 when the detection results of the weight are the same or roughly the same for multiple consecutive times. This makes it possible to determine that the solid dopant D is fully sublimated, and to automatically determine that the addition of the dopant into the silicon melt M is completed.

After the time T3, the dopant gas Gd completely sublimated in the dopant adding device 3, is not fully discharged from the dopant adding device 3 in a short time. It thus takes time before all the residual dopant gas Gd is blown to the silicon melt M to be dissipated. If the dopant adding device 3 is moved upward at the time T3, the amount of the dopant added to the silicon melt M will have a slight error. Such an error is negligible in growing the monocrystalline silicon SM with extremely low resistivity to which a large amount of dopant is added, but the resistivity may vary in growing a monocrystalline silicon SM with high resistivity. Thus, the standby period P is more preferably provided after the time T3 to stand by until all the residual dopant gas Gd in the dopant adding device 3 is blown to the silicon melt M to be dissipated.

The standby period P is a period from the time T3 to all the dopant gas Gd in the dopant adding device 3 is presumed to be blown to the silicon melt M. The standby period P is set to 1 minute to 30 minutes, and stored in the storage 43. The standby period P can be determined through simulations and/or experiments. The standby period P is preferably set in accordance with at least one of the type of the dopant or the total weight of the solid dopant D charged in the dopant adding device 3.

The growth controller 47 pulls up the seed crystal SC after bringing the seed crystal SC into contact with the silicon melt M to which the dopant is added, to grow the monocrystalline silicon SM. The growth controller 47 receives the detection result of the weight of the growing monocrystalline silicon SM from the load cell 264, and adjusts manufacturing conditions so that the monocrystalline silicon SM has a desired shape.

### Monocrystalline Silicon Manufacturing Method

A monocrystalline silicon manufacturing method will be described below. Here, a case will be described in which it is determined that the addition of the dopant into the silicon melt M is completed at the time T4 when the standby period P has elapsed since the time T3 when the standard state is reached.

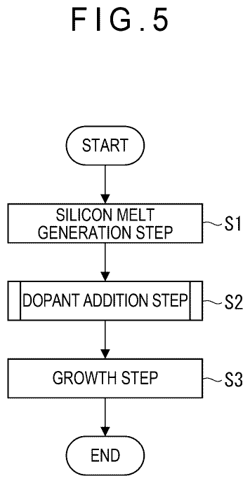

As illustrated in FIG. 5, the growth controller 47 of the control device 4 generates the silicon melt M by a known method (Step S1: silicon melt generation step). In the silicon melt generation step (Step S1), the gate valve 213 is opened. The inert gas Gf is supplied only from the first gas supply section 214 and the internal gas Gn is discharged only from the second gas discharge section 217, maintaining the inside of the chamber 21 at a reduced pressure.

The dopant addition control device 5 of the control device 4 performs a dopant addition step for adding the dopant into the silicon melt M (Step S2).

The growth controller 47 performs a growth step to grow the monocrystalline silicon SM by pulling up the seed crystal SC after bringing the seed crystal SC into contact with the silicon melt M to which the dopant is added (Step S3).

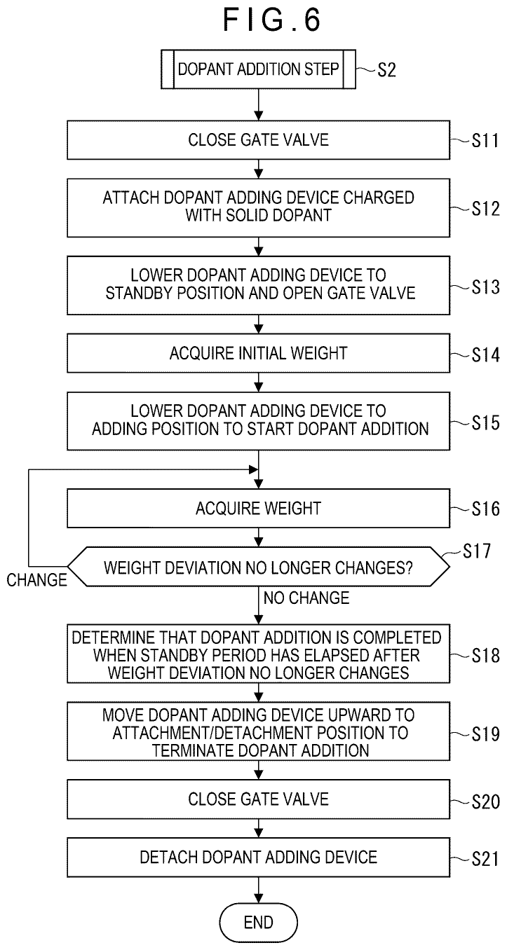

As illustrated in FIG. 6, in the dopant addition step (Step S2), the addition start controller 45 of the dopant addition control device 5 controls the gate valve driver 275 to close the gate valve 213 (Step S11). In Step S11, the pull chamber 212 is isolated from the main chamber 211 having the inert gas atmosphere.

The addition start controller 45 closes the gate valve 213, and controls the second gas supply controller 273 to supply the inert gas Gf into the main chamber 211. The addition start controller 45 controls the first gas supply controller 271 to stop the supply of the inert gas Gf into the pull chamber 212.

After the pressure inside the pull chamber 212 is set at the atmospheric pressure, an operator or a non-illustrated attachment/detachment device attaches the dopant adding device 3 charged with the solid dopant D to a lower end of the wire 261 at an attachment/detachment position (Step S12).

After the dopant adding device 3 is attached, the addition start controller 45 controls the first gas supply controller 271 to supply the inert gas Gf into the pull chamber 212, and controls the first gas discharge controller 272 to discharge the inert gas Gf from the pull chamber 212, thereby placing the inside of the pull chamber 212 at a reduced pressure.

The addition start controller 45 drives the motor 263 to lower the dopant adding device 3 to a standby position above the gate valve 213, and then controls the gate valve driver 275 to open the gate valve 213 (Step S13).

The addition start controller 45 opens the gate valve 213, and controls the second gas supply controller 273 to stop the supply of the inert gas Gf into the main chamber 211 from the second gas supply section 216. Further, the addition start controller 45 controls the first gas discharge controller 272 to stop the discharge of the inert gas Gf from the first gas discharge section 215, and controls the second gas discharge controller 274 to adjust the amount of the gas to be discharged so that the pressure inside the main chamber 211 becomes a pressure suitable for adding the dopant.

The addition start controller 45 acquires the detection result of the weight detected by the load cell 264 as an initial weight (Step S14). The addition start controller 45 may acquire the initial weight before the dopant adding device 3 is lowered to the standby position, or may acquire the initial weight after the dopant adding device 3 is lowered to the standby position above the gate valve 213 and before the gate valve 213 is opened.

The addition start controller 45 starts the dopant addition by driving the motor 263 to unwind the wire 261 and lower the dopant adding device 3 to an adding position near the silicon melt M (Step S15).

The processes in Steps S11 to S15 define an addition start step.

When a predetermined detection standby period has elapsed after the process in Step S15 is performed at the time T1 illustrated in FIG. 4, the addition termination controller 46 acquires the detection result of the weight detected by the load cell 264 (Step S16). The detection standby period, which is not particularly limited, is for instance, 30 seconds. The addition termination controller 46 determines based on the weight acquired in Step S16 whether the weight deviation with reference to the initial weight no longer changes (Step S17).

When determining that the weight deviation changes (Step S17: CHANGE), the addition termination controller 46 of the dopant addition control device 5 acquires the detection result of the weight after the detection standby period has elapsed (Step S16).

When determining that the weight deviation no longer changes (Step S17: NO CHANGE), the addition termination controller 46 determines that the addition of the dopant is completed when the standby period P has elapsed after the weight deviation no longer changes (Step S18).

The addition termination controller 46 terminates the addition of the dopant by driving the motor 263 to wind the wire 261 and move the dopant adding device 3 upward to the attachment/detachment position (Step S19).

The processes in Steps S16 to S19 define an addition termination step.

The addition termination controller 46 controls the gate valve driver 275 to close the gate valve 213 (Step S20). The addition termination controller 46 closes the gate valve 213, and controls the second gas supply controller 273 to supply the inert gas Gf into the main chamber 211. The addition termination controller 46 controls the first gas supply controller 271 to stop the supply of the inert gas Gf into the pull chamber 212.

After the pressure in the pull chamber 212 is set at the atmospheric pressure, an operator or the attachment/detachment device detaches the dopant adding device 3 from the wire 261 (Step S21).

Subsequently, an operator or the attachment/detachment device attaches the seed crystal SC to the wire 261, and the growth step in Step S3 is performed.

### Effects of Exemplary Embodiment

After lowering the dopant adding device 3 charged with the solid dopant D to the adding position and starting the dopant addition, the dopant addition control device 5 determines that the addition of the dopant into the silicon melt M is completed when the weight deviation with reference to the initial weight no longer changes (i.e. when the weight no longer changes) based on the detection result of the load cell 264, and moves the dopant adding device 3 upward.

Thus, even when the sublimation rate of the solid dopant D changes due to, for instance, a change in the heat environment in the chamber 21, it is possible to appropriately determine that all the solid dopant D is sublimated and the dopant addition is completed.

This improves the production efficiency, because the process can quickly proceed to the growth step after the addition of all dopant is actually completed. Furthermore, since the process is inhibited from proceeding to the growth step in a state where the dopant added to the silicon melt M is evaporating or before all the dopant has been added, the monocrystalline silicon SM having desired resistivity can be produced.

The dopant addition control device 5 determines that the addition of the dopant is completed at the time T4 when the standby period P has elapsed, the standby period P being a period from the time T3 at which the weight detected by the load cell 264 no longer changes to all the dopant gas Gd in the dopant adding device 3 is presumed to be blown to the silicon melt M.

Thus, the process is more reliably inhibited from proceeding to the growth step before all the dopant has been added, and the monocrystalline silicon SM having desired resistivity can be produced.

The dopant addition control device 5 determines whether the addition of the dopant is completed by the load cell 264 for detecting the weight of the growing monocrystalline silicon SM.

Therefore, there is no need to provide the monocrystalline silicon manufacturing system 1 with a weight detector used only to determine the completion of dopant addition, and the monocrystalline silicon manufacturing system 1 can be simplified.

### Modifications

In the above exemplary embodiment, a state where the weight deviation no longer changes is exemplified as the standard state. However, the standard state may be defined as a state where the weight acquired in Step S16 no longer changes without acquiring the initial weight in Step S14. Alternatively, the weight of the dopant adding device 3 alone may be measured before attaching the dopant adding device 3 to the wire 261, and a state where the weight detected by the load cell 264 is equal to the weight of the dopant adding device 3 alone may be determined as the standard state.

In the above exemplary embodiment, the completion of dopant addition is determined at the time T4 when the standby period P has elapsed since the time T3 when the standard state is reached. However, the completion of dopant addition may be determined at the time T3 when the standard state is reached.

With the above modified configurations, even when the sublimation rate of the solid dopant D changes due to, for instance, a change in the heat environment in the chamber 21, it is possible to appropriately determine that all the solid dopant D is sublimated and the dopant addition is completed.

In the above exemplary embodiment, the load cell 264, which detects the weight of the growing monocrystalline silicon SM, is used to determine whether the dopant addition is completed. However, a weight detector other than the load cell 264 may be used. Examples of such a weight detector include a weight measuring device on which the drum 262 is placed.

What is claimed is:

1. A dopant addition method, comprising:
attaching a dopant adding device charged with a volatile solid dopant to a first end of a wire, lowering the dopant adding device to an adding position above a surface of a silicon melt in a crucible placed in a chamber, and blowing a dopant gas generated by sublimation of the solid dopant to the silicon melt; and
determining that addition of the dopant to the silicon melt is completed when a weight of the dopant adding device attached to the first end of the wire detected by a weight detector reaches a standard state, and moving the dopant adding device upward, wherein
the standard state is a state where the weight detected by the weight detector no longer changes or a state where the weight detected by the weight detector is equal to a weight of the dopant adding device alone.

2. The dopant addition method according to claim 1, wherein
it is determined that the addition of the dopant to the silicon melt is completed when a predetermined standby period has elapsed since the standard state is reached, and
the standby period is a period from a time when the standard state is reached to all the dopant gas in the dopant adding device is presumed to be blown to the silicon melt.

3. The dopant addition method according to claim 1, wherein
a drum configured to be rotated by driving a motor to wind or unwind the wire is fixed to a second end of the wire,
the weight detector is a load cell configured to detect a load acting on the motor to detect the weight of the dopant adding device attached to the first end of the wire, and
the dopant adding device is configured to be moved by controlling the motor.

4. A monocrystalline silicon manufacturing method, comprising:
adding the dopant to the silicon melt by the dopant addition method according to claim 1; and
growing monocrystalline silicon by a Czochralski method using the silicon melt to which the dopant is added.

5. A dopant addition control device, comprising:
an addition start controller configured to lower a dopant adding device charged with a volatile solid dopant and attached to a first end of a wire to an adding position above a surface of a silicon melt in a crucible and to blow a dopant gas generated by sublimation of the solid dopant to the silicon melt; and
an addition termination controller configured to determine that addition of the dopant to the silicon melt is completed when a weight of the dopant adding device attached to the first end of the wire detected by a weight detector reaches a standard state, and to move the dopant adding device upward, wherein
the standard state is a state where the weight detected by the weight detector no longer changes or a state where the weight detected by the weight detector is equal to a weight of the dopant adding device alone.

6. The dopant addition control device according to claim 5, wherein
the addition termination controller is configured to determine that the addition of the dopant to the silicon melt is completed when a predetermined standby period has elapsed since the standard state is reached, and
the standby period is a period from a time when the standard state is reached to all the dopant gas in the dopant adding device is presumed to be blown to the silicon melt.

7. The dopant addition control device according to claim 5, wherein
a drum configured to be rotated by driving a motor to wind or unwind the wire is fixed to a second end of the wire,
the weight detector is a load cell configured to detect a load acting on the motor to detect the weight of the dopant adding device attached to the first end of the wire, and
the addition start controller and the addition termination controller are configured to control the motor to move the dopant adding device.

8. A monocrystalline silicon manufacturing system, comprising:
the dopant addition control device according to claim 5;
the dopant adding device;
the wire having the first end to which the dopant adding device or a seed crystal is attached;
the weight detector; and
a growth controller configured to grow monocrystalline silicon by pulling up the seed crystal attached to the first end of the wire after bringing the seed crystal into contact with the silicon melt to which the dopant is added.

9. A monocrystalline silicon manufacturing system, comprising:
the dopant addition control device according to claim 7;
the dopant adding device;
a pulling drive unit comprising the wire having the first end to which the dopant adding device or a seed crystal is attached, the drum, and the motor;
the load cell; and
a growth controller configured to grow monocrystalline silicon by pulling up the seed crystal attached to the first end of the wire after bringing the seed crystal into contact with the silicon melt to which the dopant is added.
